(19) United States
(12) Patent Application Publication
(10) Pub. No.: US 2019/0204014 A1
(43) Pub. Date: Jul. 4, 2019

(54) DEVICE TEMPERATURE REGULATOR

(71) Applicant: DENSO CORPORATION, Kariya, Aichi-pref. (JP)

(72) Inventors: Takeshi YOSHINORI, Kariya-city (JP); Takashi YAMANAKA, Kariya-city (JP); Yoshiki KATO, Kariya-city (JP); Masayuki TAKEUCHI, Kariya-city (JP); Koji MIURA, Kariya-city (JP); Yasumitsu OMI, Kariya-city (JP)

(21) Appl. No.: 16/326,403

(22) PCT Filed: Aug. 2, 2017
(86) PCT No.: PCT/JP2017/028052

§ 371 Date: Feb. 19, 2019

(30) Foreign Application Priority Data
Sep. 9, 2016 (JP) 2016-176783

(51) Int. Cl. F28D 15/02; H01M 10/613; H01M 10/625; H01M 10/6556; H01M 10/6569; H05K 7/20

(52) U.S. Cl. CPC F28D 15/025; F28D 15/0266; H01M 10/613; H01M 10/625; H01M 2220/20; H01M 10/6569; H05K 7/20309; H05K 7/20318; H05K 7/20327; H01M 10/6556

(57) ABSTRACT

An evaporator includes a fluid chamber in which a working fluid flows. A condenser includes a gas-phase portion in which the working fluid evaporated in the evaporator flows and a liquid-phase portion in which the working fluid from the gas-phase portion, condensed by heat exchange with an external medium, flows. A gas-phase passage causes the working fluid evaporated in the evaporator to flow to the condenser. A liquid-phase passage causes the working fluid condensed in the condenser to flow to the evaporator. A bypass passage has one end connected to the liquid-phase portion of the condenser or the liquid-phase passage and another end connected to the gas-phase portion of the condenser or the gas-phase passage. A flow rate of a liquid-phase working fluid per unit volume in the bypass passage is smaller than a flow rate of a liquid-phase working fluid per unit volume in the liquid-phase portion of the condenser or the liquid-phase passage.

### CROSS REFERENCE TO RELATED APPLICATION

This application is based on Japanese Patent Application No. 2016-176783 filed on Sep. 9, 2016, the contents of which are incorporated herein by reference in its entirety.

### FIELD OF THE INVENTION

The present disclosure relates to a device temperature regulator that regulates a temperature of a target device.

### BACKGROUND ART

In recent years, a technique of using thermosiphon in a device temperature regulator has been studied to regulate the temperature of electric devices, including electrical storage devices mounted on electrically-driven vehicles, such as electric vehicles and hybrid vehicles.

The device temperature regulator described in Patent Document 1 includes an evaporator provided on a side surface of a battery as the electrical storage device and a condenser provided above the evaporator. The evaporator and the condenser are annually connected by two pipes, in which a refrigerant as a working fluid is enclosed. In the device temperature regulator, when the battery generates heat, a liquid-phase refrigerant boils in the evaporator, and consequently the battery is cooled by latent heat of evaporation at that time. The gas-phase refrigerant formed in the evaporator flows through a gas-phase passage formed by one of the two pipes to enter the condenser. In the condenser, the gas-phase refrigerant is condensed by heat exchange with an external medium outside of the condenser. The liquid-phase refrigerant formed in the condenser flows by gravity through the liquid-phase passage formed by the other of the two pipes and then flows into the evaporator. Such natural circulation of the refrigerant is used to cool the battery as the target device.

The device temperature regulator as used herein implies general devices that regulate the temperature of a target device by a thermosiphon system. That is, such device temperature regulators include any device that cools a target device, that heats a target device, or that both cools and heats a target device.

### RELATED ART DOCUMENTS

### Patent Document

[Patent Document 1]
Japanese Unexamined Patent Application Publication No. 2015-041418

### SUMMARY OF INVENTION

In the device temperature regulator described in the Patent Document 1 mentioned above, when the liquid-phase refrigerant in the evaporator boils due to heat generated from the battery, and the gas-phase refrigerant is converted into bubbles in the liquid-phase refrigerant, in some cases, a few bubbles flow into the liquid-phase passage and then backward against the flow of the liquid-phase refrigerant by a buoyant force. When entering the condenser, the bubbles push up the liquid-phase refrigerant inside the condenser to blow up the liquid-phase refrigerant from the upper liquid surface, or to make the bubbles burst, causing an abnormal noise. In addition, when the generation of the liquid-phase refrigerant in the condenser is inhibited by the bubbles entering the condenser, the liquid-phase refrigerant cannot be smoothly supplied from the condenser to the evaporator through the liquid-phase passage. Thus, the cooling capacity of the device temperature regulator for the battery might be reduced.

Therefore, it is an object of the present disclosure to provide a device temperature regulator capable of suppressing the generation of abnormal noise.

According to an aspect of the present disclosure, a device temperature regulator for regulating a temperature of a target device includes an evaporator, a condenser, a gas-phase passage, a liquid-phase passage and a bypass passage. The evaporator includes a fluid chamber in which a working fluid flows, and is configured to cool the target device by latent heat of evaporation when the working fluid in the fluid chamber evaporates by absorbing heat from the target device. The condenser is provided above the evaporator in a gravitational direction, and includes a gas-phase portion in which the working fluid evaporated in the evaporator flows and a liquid-phase portion in which the working fluid from the gas-phase portion, condensed by heat exchange with an external medium outside of the condenser, flows. The gas-phase passage has one end connected to the evaporator and another end connected to the gas-phase portion of the condenser, and the gas-phase passage causes the working fluid evaporated in the evaporator to flow to the condenser. The liquid-phase passage has one end connected to the evaporator and another end connected to the liquid-phase portion of the condenser. The liquid-phase passage is configured to cause the working fluid condensed in the condenser to flow to the evaporator. The bypass passage has one end connected to the liquid-phase portion of the condenser or the liquid-phase passage and another end connected to the gas-phase portion of the condenser or the gas-phase passage. Furthermore, the bypass passage is configured such that a flow rate of a liquid-phase working fluid per unit volume in the bypass passage is smaller than a flow rate of a liquid-phase working fluid per unit volume in the liquid-phase portion of the condenser or the liquid-phase passage.

When the working fluid boils in the fluid chamber of the evaporator with heat absorbing from the target device, and the gas-phase working fluid is converted into bubbles in the liquid-phase working fluid, some of the bubbles flow into the liquid-phase passage and then flow backward against the flow of the liquid-phase working fluid by a buoyant force in some cases. Also, when bubbles are generated in the liquid-phase passage, the bubbles sometimes flow backward against the flow of the liquid-phase working fluid by the buoyant force. The bypass passage is configured such that a flow rate of a liquid-phase working fluid per unit volume in the bypass passage is smaller than a flow rate of a liquid-phase working fluid per unit volume in the liquid-phase portion of the condenser or the liquid-phase passage. Thus, the bubbles that flow backward against the flow of the liquid-phase working fluid flowing through the liquid-phase portion of the condenser or liquid-phase passage tend to easily flow from the liquid-phase portion of the condenser or the liquid-phase passage to the bypass passage. Therefore, the bubbles can be restricted from pushing up the liquid-phase working fluid in the liquid-phase portion of the condenser and blowing up the liquid-phase working fluid from the upper liquid surface, and also restricted from bursting to make abnormal noise. Furthermore, the bubbles are suppressed from flowing backward to the upstream side with respect to the connection portion between the liquid-phase portion of the condenser or the liquid-phase passage and the bypass passage. Thus, the liquid-phase working fluid is smoothly formed in the condenser and also smoothly supplied from the condenser to the evaporator through the liquid-phase passage. Therefore, the device temperature regulator can improve the cooling performance for the target device.

According to another aspect, the device temperature regulator includes an outer bypass passage that has one end connected to the liquid-phase passage and another end connected to the gas-phase portion of the condenser or the gas-phase passage. The outer bypass passage is configured such that a flow rate of a liquid-phase working fluid per unit volume in the outer bypass passage is smaller than a flow rate of a liquid-phase working fluid per unit volume in the liquid phase passage.

Thus, bubbles that flow backward against the flow of the liquid-phase working fluid flowing through the liquid-phase passage tend to easily flow from the liquid-phase passage to the outer bypass passage. Therefore, the bubbles can be restricted from pushing up the liquid-phase working fluid in the liquid-phase portion of the condenser and blowing up the liquid-phase working fluid from the upper liquid surface, and also restricted from bursting to make abnormal noise. Furthermore, the bubbles are suppressed from flowing backward to the upstream side with respect to the connection portion between the liquid-phase passage and the bypass passage. Consequently, the liquid-phase working fluid is smoothly formed in the condenser and also smoothly supplied from the condenser to the evaporator via the liquid-phase passage. Therefore, the device temperature regulator can improve the cooling performance for the target device.

According to another aspect, the condenser includes an upper tank, a lower tank disposed below the upper tank in the gravitational direction, and a plurality of heat exchange tubes connecting the upper tank and the lower tank. The device temperature regulator further includes an inside bypass passage that has one end connected to the lower tank of the condenser and another end connected to the upper tank of the condenser. The inside bypass passage is configured such that a flow rate of a liquid-phase working fluid per unit volume in the inside bypass passage is smaller than a flow rate of a liquid-phase working fluid per unit volume in the heat exchange tubes.

Thus, when entering the liquid-phase portion of the condenser from the liquid-phase passage, the bubbles that flow backward against the flow of the liquid-phase working fluid flowing through the liquid-phase passage tend to flow more easily to the inner bypass passage than to the plurality of heat exchange tubes. Consequently, the bubbles can be restricted from entering the heat exchange tubes in the condenser. Therefore, the bubbles can be restricted from pushing up the liquid-phase working fluid in the heat exchange tubes and blowing up the liquid-phase working fluid from the upper liquid surface, and also restricted from bursting in the heat exchange tubes to make abnormal noise. Furthermore, the liquid-phase working fluid is smoothly formed in the plurality of heat exchange tubes of the condenser, so that the liquid-phase working fluid can be smoothly supplied from the condenser to the evaporator through the liquid-phase passage. Therefore, the device temperature regulator can improve the cooling performance for the target device.

### BRIEF DESCRIPTION OF THE DRAWINGS

FIG. 1 is a configuration diagram of a device temperature regulator according to a first embodiment;

FIG. 2 is a partially enlarged view of the device temperature regulator according to the first embodiment;

FIG. 3 is another partially enlarged view of the device temperature regulator according to the first embodiment;

FIG. 4 is a partially enlarged view of a device temperature regulator according to a second embodiment;

FIG. 5 is a partially enlarged view of a device temperature regulator according to a third embodiment;

FIG. 6 is a partially enlarged view of a device temperature regulator according to a fourth embodiment;

FIG. 7 is a partially enlarged view of a device temperature regulator according to a fifth embodiment;

FIG. 8 is another partially enlarged view of the device temperature regulator according to the fifth embodiment;

FIG. 9 is a partially enlarged view of a device temperature regulator according to a sixth embodiment;

FIG. 10 is a partially enlarged view of a device temperature regulator according to a seventh embodiment;

FIG. 11 is a partially enlarged view of a device temperature regulator according to an eighth embodiment;

FIG. 12 is a partially enlarged view of a device temperature regulator in a first comparative example;

FIG. 13 is another partially enlarged view of the device temperature regulator in the first comparative example; and

FIG. 14 is a partially enlarged view of a device temperature regulator in a second comparative example.

### DESCRIPTION OF EMBODIMENTS

Hereinafter, embodiments of the present disclosure will be described with reference to the accompanying drawings. In the respective embodiments below, the same or equivalent parts will be described with the same reference characters. In the drawings, when the same configuration is shown in a plurality of sites, some of them only are denoted by the reference character.

### First Embodiment

A first embodiment will be described below with reference to the accompanying drawings. A device temperature regulator of the present embodiment regulates the temperature of a target device, i.e., an electric device, such as an electrical storage device or an electronic circuit, mounted on electrically-driven vehicles, including electric vehicles and hybrid vehicles, by cooling the target device. In the drawings, arrows indicating up and down represent upward and downward directions of gravitational force when the device temperature regulator is mounted on a vehicle and the vehicle is stopped at a horizontal plane.

First, the target device to be temperature-regulated by a device temperature regulator 1 of the present embodiment will be described.

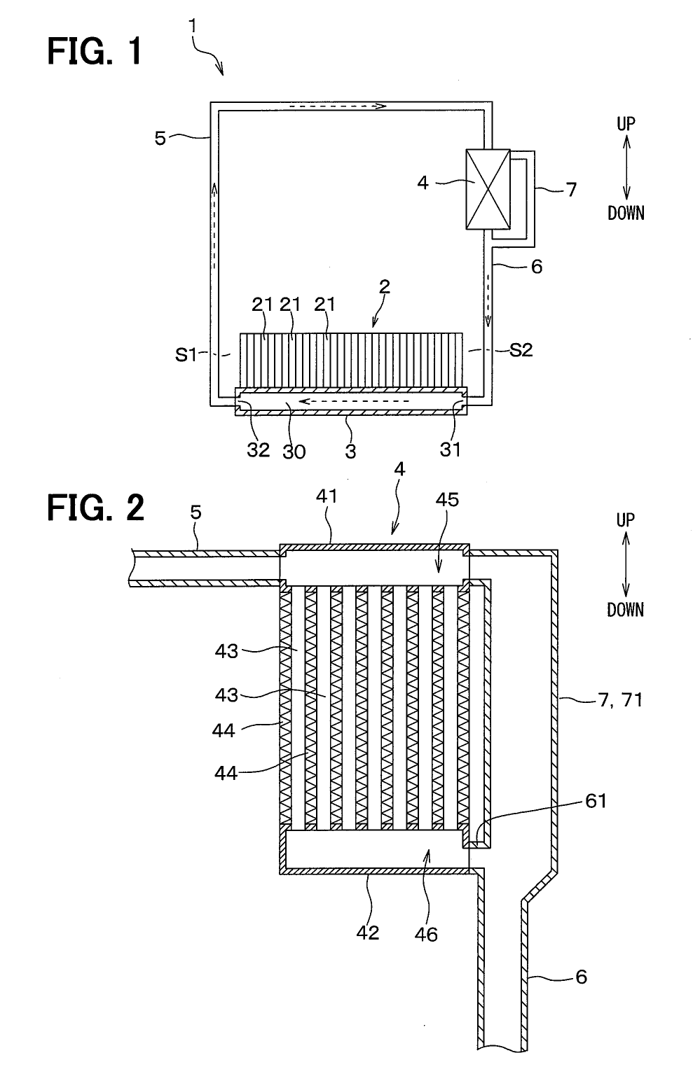

As shown in FIG. 1, the target device to be temperature-regulated by the device temperature regulator 1 of the present embodiment is an assembled battery 2 (hereinafter referred to as a “battery”). The target device may be a battery pack that includes the battery 2, a power converter (not shown), and the like.

The battery 2 is used as a power source for vehicles, such as electric vehicles and hybrid vehicles, which can travel using a traveling electric motor. The battery 2 is configured of a stack of a plurality of battery cells 21 each having a rectangular parallelepiped shape. The plurality of battery cells 21 configuring the battery 2 is electrically connected in series. Each battery cell 21 is configured of, for example, a rechargeable-dischargeable secondary battery, such as a lithium ion battery or a lead acid battery. The battery cell 21 is not limited to a rectangular parallelepiped shape and may have any other shape, such as a cylindrical shape. The battery 2 may include battery cells 21 electrically connected in parallel.

The battery 2 is connected to a power converter (not shown) and a motor generator (not shown), included in the vehicle. The power converter is, for example, a device that converts a DC current supplied from the battery 2 into an AC current and discharges the converted AC current to various electric loads, such as the traveling electric motor. The motor generator is a device that inversely converts the traveling energy of the vehicle into electric energy during regenerative braking of the vehicle and supplies the inversely converted electric energy as regenerative electric power to the battery 2 via an inverter or the like.

The battery 2 self-generates heat when supplying the electric power or the like while the vehicle is traveling. Consequently, the battery 2 is at an extremely high temperature in some cases. When the battery 2 reaches an extremely high temperature, the deterioration of the battery cells 21 is accelerated. Thus, the output and input of the battery 2 need to be restricted so as to reduce the self-generated heat. In order to secure the output and input of the battery cells 21, a cooling unit for maintaining the temperature of the battery 2 at a predetermined temperature or lower is required.

The electrical storage device including the battery 2 is often disposed under the floor of the vehicle or under the trunk room. Thus, the temperature of the battery 2 gradually increases not only during traveling of the vehicle, but also during parking or the like in summer, and eventually the battery 2 reaches an extremely high temperature. When the battery 2 is left under a high-temperature environment, the deterioration of the battery 2 is accelerated, and thus its lifetime is significantly reduced. Because of this, the temperature of the battery 2 is desired to be maintained at a predetermined temperature or lower even during parking of the vehicle or the like.

As the battery 2 includes the configuration of the respective battery cells 21 electrically connected in series, the input and output characteristics of the entire battery are determined depending on the state of the battery cell 21 that is deteriorated the most among the respective battery cells 21. Thus, when the respective battery cells 21 have different temperatures, the progression of deterioration of the respective battery cells 21 is varied, degrading the input and output characteristics of the entire battery. Therefore, in order to cause the battery 2 to exhibit the desired performance for a long time, it is important to equalize the temperature of each battery cell 21 to reduce the temperature variation.

In general, an air-cooled cooling unit using a blower, a cooling unit using a coolant, or a cooling unit using a vapor compression refrigeration cycle is employed as a cooler for cooling the battery 2.

However, the air-cooled cooling unit by the blower only blows the air inside or outside the vehicle cabin to the battery 2 and consequently cannot gain a sufficient cooling capability to cool the battery 2 in some cases. In the air-cooled cooling unit or the cooling unit by the coolant, there occur variations in the cooling temperature between the battery cell 21 on the upstream side of the air or coolant flow and the battery cell 21 on the downstream side thereof in some cases.

The cooling unit using cold heat in the refrigeration cycle has a high cooling capability of the battery 2, but must drive a compressor or the like that has a large power consumption during parking of the vehicle. This might lead to an increase in power consumption and an increase in noise.

The device temperature regulator 1 of the present embodiment does not force the refrigerant as the working fluid to circulate by using the compressor, but employs thermosiphon system, which regulates the temperature of the battery 2 by using the natural circulation of the refrigerant.

Next, the device temperature regulator 1 will be described.

As shown in FIG. 1, the device temperature regulator 1 includes an evaporator 3, a condenser 4, a gas-phase passage 5, a liquid-phase passage 6, a bypass passage 7, and the like, and these constituent members are connected to each other to configure a loop-type thermosiphon. In the device temperature regulator 1 with its interior evacuated, a predetermined amount of refrigerant is enclosed therein. As the refrigerant, various materials, such as, for example, R134a, R1234yf, carbon dioxide, and water, can be employed. As indicated by the dot-and-dash lines S1 and S2 in FIG. 1, the amount of the refrigerant is preferably set such that the upper liquid surface of the liquid-phase refrigerant is located at some point of the gas-phase passage 5 and at some point of the liquid-phase passage 6 before the cooling of the battery 2 is started. When the refrigerant circulates in the direction indicated by the dashed arrow in FIG. 1, the upper liquid surface of the liquid-phase refrigerant is displaced accordingly.

The evaporator 3 constitutes a hermetically sealed case. The evaporator 3 is formed in a flat shape and provided in a position facing the lower surface of the battery 2. The evaporator 3 is preferably made of a material having excellent thermal conductivity, such as aluminum or copper. The evaporator 3 may be provided to enable heat transfer between the plurality of battery cells 21 and the evaporator 3. For example, the evaporator 3 may be provided in a position that faces the side surface or upper surface of the battery 2. The shape and size of the evaporator 3 can be arbitrarily set in accordance with a space on the vehicle where the evaporator 3 is mounted.

The evaporator 3 has a fluid chamber 30 inside. The fluid chamber 30 is preferably filled with the liquid-phase refrigerant before the cooling of the battery 2 is started. Actually, the liquid-phase refrigerant and the gas-phase refrigerant may be included in the fluid chamber 30. When the battery 2 self-generates heat due to electric storage, electric discharge, or the like, the heat is transferred from the battery 2 to the evaporator 3, and subsequently the liquid-phase refrigerant in the fluid chamber 30 absorbs the heat to evaporate. At that time, the liquid-phase refrigerant evaporates within the entire fluid chamber 30, so that the plurality of battery cells 21 is cooled substantially uniformly by the latent heat of evaporation. Therefore, the evaporator 3 can equalize the temperatures of the plurality of battery cells 21 while reducing variations in the temperature among the battery cells 21 and can also cool the battery cells 21.

As mentioned above, the battery 2 cannot exhibit sufficient functions and is sometimes deteriorated or damaged when being at a high temperature. The battery 2 has its input and output characteristics determined as a whole in accordance with the characteristics of the most deteriorated battery cell 21. For this reason, the evaporator 3 equalizes the temperatures of the plurality of battery cells 21 by cooling using the latent heat of evaporation, and thereby cools the battery cells 21, thus enabling the battery 2 to exhibit the desired performance for a long period of time.

The gas-phase passage 5 and the liquid-phase passage 6 are connected to the evaporator 3. A portion where the evaporator 3 and the liquid-phase passage 6 are connected is referred to as a first opening 31, whereas a portion where the evaporator 3 and the gas-phase passage 5 are connected is referred to as a second opening 32. In the evaporator 3, the first opening 31 and the second opening 32 are preferably spaced apart from each other. Thus, when the refrigerant circulates through the thermosiphon loop, the flow of the refrigerant directed from the first opening 31 to the second opening 32 is generated in the evaporator 3. In FIG. 1, both the first opening 31 and the second opening 32 are provided on the side surfaces of the evaporator 3, but the positions of the first opening 31 and the second opening 32 are not limited to the side surfaces and may be either an upper surface or a lower surface of the evaporator 3.

The condenser 4 is provided above the evaporator 3 in the gravitational direction. The gas-phase passage 5 connects the evaporator 3 and the condenser 4. The gas-phase passage 5 has one end connected to the second opening 32 of the evaporator 3 and the other end connected to an upper tank 41 of the condenser 4. The gas-phase passage 5 enables the gas-phase refrigerant evaporated in the evaporator 3 to flow to the condenser 4. The gas-phase passage 5 allows mainly the gas-phase refrigerant to flow therethrough, but sometimes allows a refrigerant in a gas-liquid two-phase state or a liquid-phase refrigerant to flow therethrough.

The condenser 4 is preferably made of a material having excellent thermal conductivity, such as aluminum or copper. The shape and size of the condenser 4 can be arbitrarily set in accordance with a space on the vehicle where the condenser 4 is mounted. As shown in FIG. 2, the condenser 4 includes the upper tank 41, a lower tank 42 disposed below the upper tank 41 in the gravitational direction, and a plurality of heat exchange tubes 43 connecting the upper tank 41 and the lower tank 42. A plurality of fins 44 is provided on the outside of the plurality of heat exchange tubes 43. The gas-phase refrigerant supplied from the gas-phase passage 5 to the upper tank 41 flows from the upper tank 41 into the plurality of heat exchange tubes 43. The gas-phase refrigerant condenses through heat exchange with an external medium located outside the condenser 4 when flowing through the plurality of heat exchange tubes 43. The liquid-phase refrigerant formed by the plurality of heat exchange tubes 43 flows into the lower tank 42 under its own weight. In the condenser 4, a region through which the gas-phase refrigerant evaporated in the evaporator 3 flows is referred to as a gas-phase portion 45, whereas a region through which the liquid-phase refrigerant produced by condensation of the gas-phase refrigerant from the gas-phase portion 45 flows is referred to as a liquid-phase portion 46. The gas-phase portion 45 is formed above the liquid-phase portion 46 in the gravitational direction. However, when the refrigerant in the gas-liquid two-phase state flows through the condenser 4, the boundary between the gas-phase portion 45 and the liquid-phase portion 46 is not uniquely defined.

As shown in FIG. 1, the liquid-phase passage 6 connects the evaporator 3 and the condenser 4. The liquid-phase passage 6 has one end connected to the first opening 31 of the evaporator 3 and the other end connected to the lower tank 42 of the condenser 4. The liquid-phase passage 6 enables the liquid-phase refrigerant condensed in the condenser 4 to flow to the evaporator 3 by the gravity. The liquid-phase passage 6 allows mainly the liquid-phase refrigerant to flow therethrough, but sometimes allows a refrigerant in a gas-liquid two-phase state or a gas-phase refrigerant to flow therethrough.

Subsequently, a characteristic configuration of the device temperature regulator 1 will be described.

As shown in FIG. 2, the liquid-phase passage 6 includes an extending portion 61 that extends from the liquid-phase portion 46 of the condenser 4 in a direction intersecting the gravitational direction. The bypass passage 7 connects the liquid-phase passage 6 and a gas-phase portion 45 of the condenser 4. The bypass passage 7 has one end connected to the liquid-phase passage 6 and the other end connected to the gas-phase portion 45 of the condenser 4. In the present embodiment, the bypass passage 7 is hereinafter referred to as an outer bypass passage 71. In detail, one end of the outer bypass passage 71 is connected to a part of the extending portion 61 of the liquid-phase passage 6 located on an opposite side to the liquid-phase portion 46 of the condenser 4. The other end of the outer bypass passage 71 is connected to the upper tank 41 which is the gas-phase portion 45 of the condenser 4. The outer bypass passage 71 generates less liquid-phase refrigerant than the plurality of heat exchange tubes 43 described above. The outer bypass passage 71 has a larger passage inner diameter, equivalent diameter, or passage cross-sectional area than each of the heat exchange tubes 43 of the condenser 4. Thus, the outer bypass passage 71 has a configuration in which the flow rate of the liquid-phase refrigerant per unit volume is smaller than that in the heat exchange tubes 43 of the condenser 4 and the liquid-phase passage 6.

As mentioned above, when the battery 2 self-generates heat due to electric storage, electric discharge, or the like, the heat is transferred from the battery 2 to the evaporator 3, and thereby the liquid-phase refrigerant in the fluid chamber 30 evaporates by absorbing the heat. At this time, when the flow speed of the refrigerant flowing through the evaporator 3 from the first opening 31 to the second opening 32 is small, the gas-phase refrigerant formed from the liquid-phase refrigerant in the evaporator 3 becomes bubbles, and the bubbles flow from the first opening 31 into the liquid-phase passage 6 in some cases. In addition, even when the amount of heat generated by the battery 2 increases drastically to cause bumping of the liquid-phase refrigerant, the bubbles generated in the liquid-phase refrigerant of the evaporator 3 are allowed to flow into the liquid-phase passage 6 from the first opening 31 in some cases.

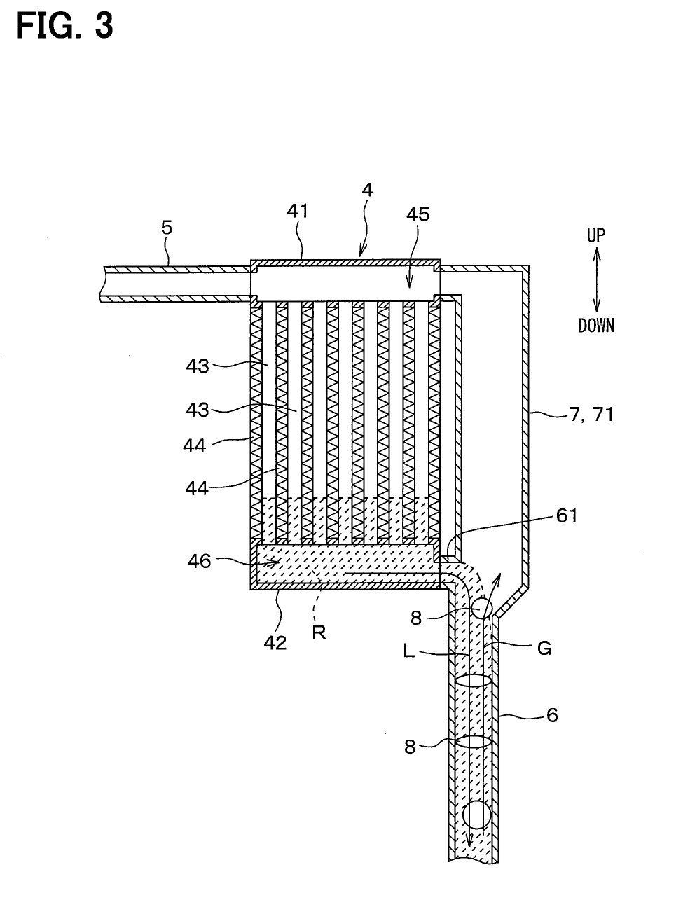

As shown in FIG. 3, the bubbles 8 flowing into the liquid-phase passage 6 rise by a buoyant force, and flow backward against the flow of the liquid-phase refrigerant that flows through the liquid-phase passage 6 by gravity. In FIG. 3, an area where the flow rate of the liquid-phase refrigerant formed by the condenser 4 and flowing through the liquid-phase passage 6 is relatively large is indicated by hatching R in dotted lines, and the flow direction of the liquid-phase refrigerant is indicated by the arrow L. The liquid-phase refrigerant flows from the liquid-phase portion 46 of the condenser 4 into the liquid-phase passage 6. At this time, the liquid-phase refrigerant flows at a larger flow rate through a part of the extending portion 61 of the liquid-phase passage 6 located close to the liquid-phase portion 46 of the condenser 4. In FIG. 3, the direction in which the bubbles 8 rise by the buoyant force and flows backward against the flow of the liquid-phase refrigerant is indicated by the arrow G.

As mentioned above, the outer bypass passage 71 has the configuration in which the flow rate of the liquid-phase refrigerant per unit volume is smaller than that in the heat exchange tubes 43 of the condenser 4 and the liquid-phase passage 6. Thus, the pressure loss, i.e., the airflow resistance, of the gas-phase refrigerant (i.e., the bubbles 8) flowing through the outer bypass passage 71 is smaller than the pressure loss of the gas-phase refrigerant (i.e., the bubbles 8) that flows backward against the flow of the liquid-phase refrigerant flowing through the liquid-phase passage 6. Therefore, the bubbles 8 rising in the liquid-phase passage 6 while flowing backward against the flow of the liquid-phase refrigerant tend to easily flow from the liquid-phase passage 6 to the outer bypass passage 71.

As mentioned above, one end of the outer bypass passage 71 is connected to a part of the extending portion 61 of the liquid-phase passage 6 located on the opposite side to the liquid-phase portion 46 of the condenser 4. Thus, the pressure loss of the gas-phase refrigerant (i.e., the bubbles 8) flowing through a part located far from the liquid-phase portion 46 of the condenser 4 is smaller than the pressure loss of the gas-phase refrigerant (i.e., the bubbles 8) flowing backward against the flow of the liquid-phase refrigerant that flows through a part of the extending portion 61 of the liquid-phase passage 6 located close to the liquid-phase portion 46 of the condenser 4. Therefore, the outer bypass passage 71 is configured such that the bubbles 8 rising in the liquid-phase passage 6 while flowing backward against the flow of the liquid-phase refrigerant tend to easily flow from the liquid-phase passage 6 to the outer bypass passage 71. The bubbles 8 flowing to the outer bypass passage 71 are caused to flow into the plurality of heat exchange tubes 43 from the upper tank 41 of the condenser 4 to become the liquid-phase refrigerant.

Next, a device temperature regulator 100 in a first comparative example will be described.

As shown in FIG. 12, the device temperature regulator 100 of the first comparative example does not include a bypass passage. Also in the device temperature regulator 100 of the first comparative example, the gas-phase refrigerant formed from the liquid-phase refrigerant in the evaporator 3 becomes bubbles 8, and the bubbles 8 flow from the first opening 31 into the liquid-phase passage 6 in some cases. Likewise, in FIG. 12, an area where the flow rate of the liquid-phase refrigerant is relatively large is indicated by hatching R in dotted lines, and the flow direction of the liquid-phase refrigerant is indicated by the arrow L. The direction in which the bubbles 8 flow backward against the flow of the liquid-phase refrigerant is indicated by the arrow G1.

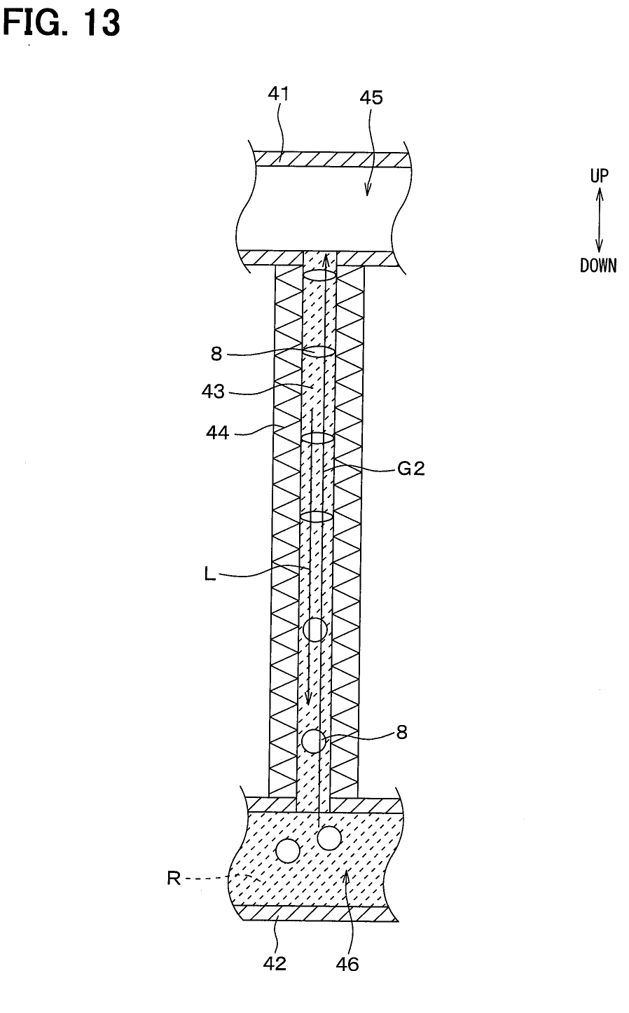

As the device temperature regulator 100 of the first comparative example does not include the outer bypass passage 71, the bubbles 8 flowing backward in the liquid-phase passage 6 intrude into the lower tank 42 of the condenser 4. As shown in FIG. 13, the bubbles 8 that have intruded into the lower tank 42 of the condenser 4 are caused to flow into the heat exchange tubes 43 and then to rise while flowing backward against the flow of the liquid-phase refrigerant as indicated by the arrow G2. Thus, the bubbles 8 might push up the liquid-phase refrigerant to blow up the liquid-phase refrigerant from the upper liquid surface or to burst, making abnormal noise. When the bubbles 8 flow backward through the heat exchange tubes 43 as indicated by the arrow G2, the flow of the liquid-phase refrigerant is worsened to inhibit the generation of the liquid-phase refrigerant in the heat exchange tubes 43. Consequently, the liquid-phase refrigerant might not be smoothly supplied from the condenser 4 to the evaporator 3 through the liquid-phase passage 6.

As compared to the first comparative example described above, the device temperature regulator 1 of the first embodiment has the following operations and effects.

(1) In the first embodiment, the outer bypass passage 71 has one end connected to the liquid-phase passage 6 and the other end connected to the gas-phase portion 45 of the condenser 4. The outer bypass passage 71 has the configuration in which the flow rate of the liquid-phase refrigerant per unit volume is smaller than that in the heat exchange tubes 43 of the condenser 4 and the liquid-phase passage 6.

Thus, the bubbles 8 that flow backward against the flow of the liquid-phase refrigerant flowing through the liquid-phase passage 6 tend to easily flow from the liquid-phase passage 6 to the outer bypass passage 71. Therefore, the bubbles 8 can be restricted from pushing up the liquid-phase refrigerant in the liquid-phase portion 46 of the condenser 4 and blowing up the liquid-phase refrigerant from the upper liquid surface and also restricted from bursting to make abnormal noise.

The bubbles 8 can be suppressed from flowing backward to the upstream side of the liquid-phase passage with respect to the connection portion between the liquid-phase passage 6 and the outer bypass passage 71. Consequently, the heat exchange tubes 43 of the condenser 4 smoothly form the liquid-phase refrigerant, so that the liquid-phase refrigerant is smoothly supplied from the condenser 4 to the evaporator 3 through the liquid-phase passage 6. Therefore, the device temperature regulator 1 can improve the cooling performance for the battery 2.

(2) In the first embodiment, the outer bypass passage 71 has one end connected to a part of the extending portion 61 of the liquid-phase passage 6 located on the opposite side to the liquid-phase portion 46 of the condenser 4.

Thus, the liquid-phase refrigerant, which flows out of the liquid-phase portion 46 of the condenser 4 to the liquid-phase passage 6, flows at a larger flow rate through the part of the extending portion 61 located close to the liquid-phase portion 46. Consequently, the bubbles 8 that flow backward against the flow of the liquid-phase refrigerant flowing through the liquid-phase passage 6 tend to easily flow from a part of the extending portion 61 located far from the liquid-phase portion 46, to the outer bypass passage 71. Therefore, the separation efficiency between the liquid-phase refrigerant flowing through the liquid-phase passage 6 and the bubbles 8 can be improved.

### Second Embodiment

A second embodiment will be described below. The second embodiment is substantially the same as the first embodiment except that the configuration of the outer bypass passage 71 is changed with respect to that of the first embodiment, and thus only differences from the first embodiment will be described.

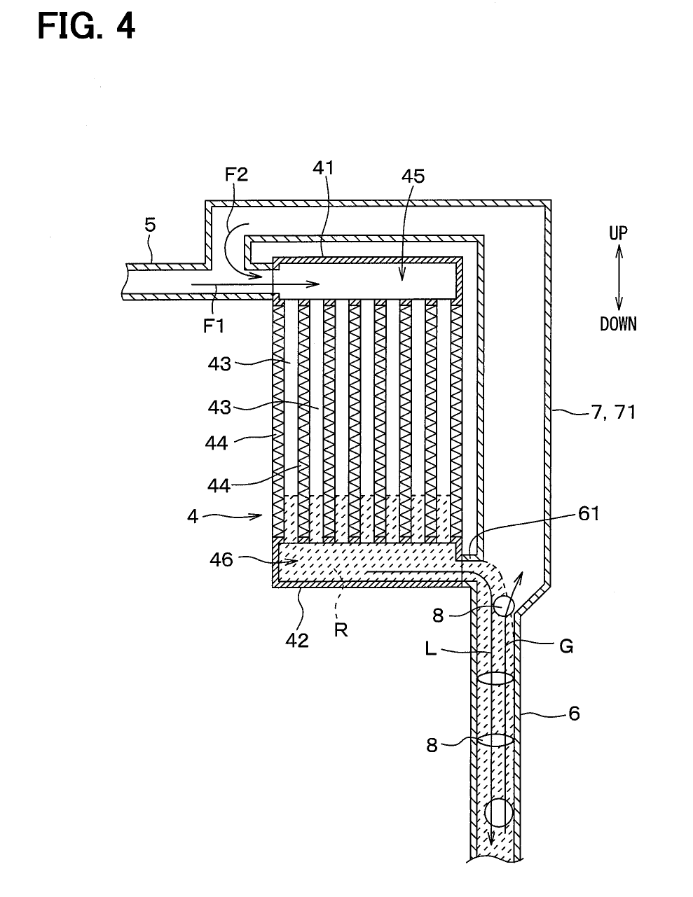

As shown in FIG. 4, in the second embodiment, the outer bypass passage 71 has one end connected to the liquid-phase passage 6 and the other end connected to the gas-phase passage 5. When the refrigerant boils in the evaporator 3 and is condensed in the condenser 4 due to a temperature difference between the evaporator 3 and the condenser 4, the flow of the gas-phase refrigerant directed from the evaporator 3 to the condenser 4 is generated in the gas-phase passage 5, as indicated by an arrow F1 in FIG. 4. Thus, the other end of the outer bypass passage 71 is connected to the gas-phase passage 5, so that the gas-phase refrigerant flowing through the outer bypass passage 71 can be drawn into the gas-phase passage 5 due to a negative pressure generated by the flow of the gas-phase refrigerant in the gas-phase passage 5, as indicated by the arrow F2. Therefore, in the second embodiment, the pressure loss of the gas-phase refrigerant becomes smaller in the outer bypass passage 71, thereby restricting the bubbles 8 flowing backward through the liquid-phase passage 6 from intruding into the lower tank 42 of the condenser 4. Consequently, the device temperature regulator 1 can suppress the generation of abnormal noise due to the burst of the bubbles 8, while suppressing the liquid-phase refrigerant from being blown up from the upper liquid surface in the condenser 4.

### Third Embodiment

A third embodiment will be described below. The third embodiment is substantially the same as the first embodiment except that the configuration of the condenser 4 is changed with respect to that of the first embodiment, and thus only differences from the first embodiment will be described.

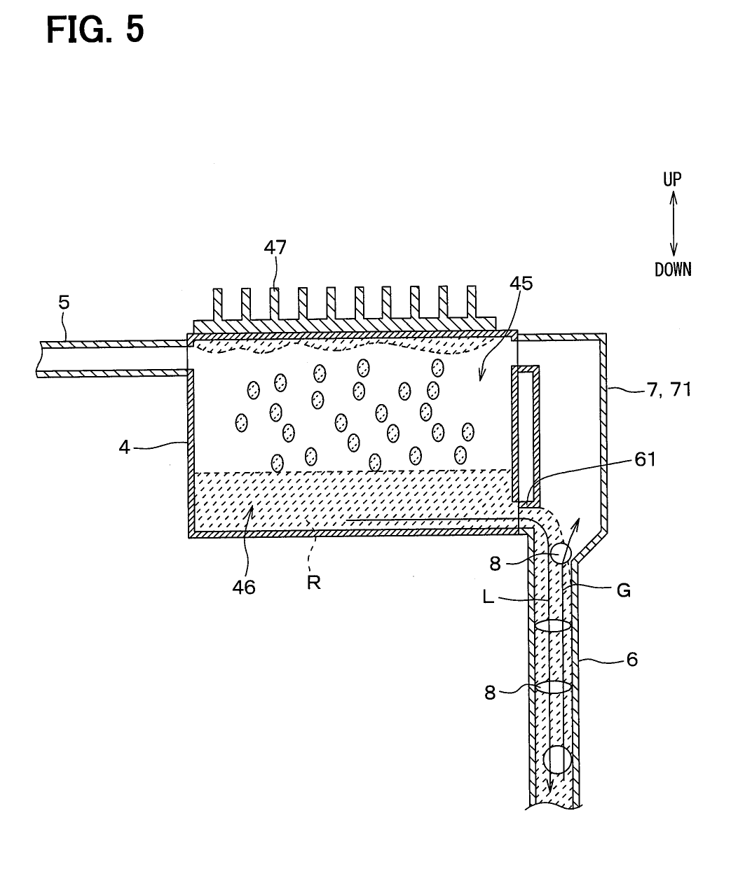

As shown in FIG. 5, in the third embodiment, the condenser 4 is configured of a sealed case, and does not include the upper tank, the lower tank, and the heat exchange tubes described in the first and second embodiments. A heat sink 47 configured of a plurality of plate-shaped members is provided on the upper outer side of the condenser 4. Each of the condenser 4 and the heat sink 47 is preferably made of a material having excellent thermal conductivity, such as aluminum or copper. The shape and size of each of the condenser 4 and the heat sink 47 can be arbitrarily set in accordance with a space on the vehicle where each of the condenser 4 and heat sink 47 is mounted.

The gas-phase refrigerant supplied from the gas-phase passage 5 into the condenser 4 is condensed by heat exchange with the external medium outside of the condenser 4. The liquid-phase refrigerant formed inside the condenser 4 flows at the bottom of the condenser 4 by gravity. In FIG. 5, the liquid-phase refrigerant formed inside the condenser 4 is indicated by hatching R in dashed lines. A region through which the gas-phase refrigerant flows is referred to as the gas-phase portion 45, whereas a region through which the liquid-phase refrigerant formed by condensing the gas-phase refrigerant in the gas-phase portion 45 flows is referred to as the liquid-phase portion 46. However, when the refrigerant inside the condenser 4 is in a gas-liquid two-phase state, the boundary between the gas-phase portion 45 and the liquid-phase portion 46 is not uniquely defined.

Also, in the third embodiment, one end of the outer bypass passage 71 is connected to a part of the extending portion 61 of the liquid-phase passage 6 located on the opposite side to the liquid-phase portion 46 of the condenser 4. The other end of the outer bypass passage 71 is connected to the gas-phase portion 45 of the condenser 4. The outer bypass passage 71 generates less liquid-phase refrigerant than the condenser 4. Thus, the outer bypass passage 71 has the configuration in which the flow rate of the liquid-phase refrigerant per unit volume in the outer bypass passage 71 is smaller than that in the liquid-phase portion 46 of the condenser 4. Therefore, the bubbles 8 rising in the liquid-phase passage 6 while flowing backward against the flow of the liquid-phase refrigerant tend to easily flow from the liquid-phase passage 6 to the outer bypass passage 71.

As mentioned above, one end of the outer bypass passage 71 is connected to a part of the extending portion 61 of the liquid-phase passage 6 located on the opposite side to the liquid-phase portion 46 of the condenser 4. Thus, the pressure loss of the gas-phase refrigerant flowing through a part located far from the liquid-phase portion 46 of the condenser 4 is smaller than the pressure loss of the gas-phase refrigerant that flows backward against the flow of the liquid-phase refrigerant flowing through a part of the extending portion 61 of the liquid-phase passage 6 located close to the liquid-phase portion 46 of the condenser 4. Therefore, the bubbles 8 rising in the liquid-phase passage 6 while flowing backward against the flow of the liquid-phase refrigerant tend to easily flow from the liquid-phase passage 6 to the outer bypass passage 71. The bubbles 8 flowing to the outer bypass passage 71 are caused to flow into the condenser 4 from the outer bypass passage 71 to become the liquid-phase refrigerant.

Here, a device temperature regulator 101 in a second comparative example will be described below.

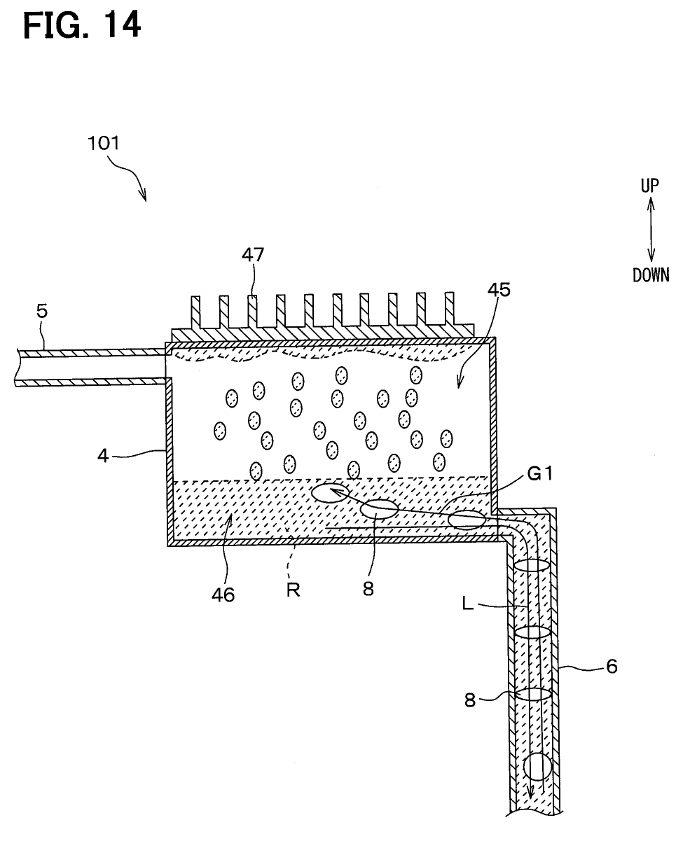

As shown in FIG. 14, the device temperature regulator 101 of the second comparative example does not include a bypass passage. Thus, bubbles 8 flowing backward in the liquid-phase passage 6 intrude into the condenser 4. The bubbles 8 might push up the liquid-phase refrigerant to blow up the liquid-phase refrigerant from the upper liquid surface or to burst, making abnormal noise. When the bubbles 8 flow into the condenser 4, the flow of the liquid-phase refrigerant is interrupted in the condenser 4. Consequently, it is supposed that the liquid-phase refrigerant cannot be smoothly supplied from the condenser 4 to the evaporator 3 through the liquid-phase passage 6.

As compared to the second comparative example described above, the device temperature regulator 1 of the third embodiment mentioned above has the following operations and effects.

In the third embodiment, the bubbles 8 that flow backward against the flow of the liquid-phase refrigerant flowing through the liquid-phase passage 6 tend to easily flow from the liquid-phase passage 6 to the outer bypass passage 71. Therefore, the bubbles 8 can be restricted from pushing up the liquid-phase refrigerant in the liquid-phase portion 46 of the condenser 4 and blowing up the liquid-phase refrigerant from the upper liquid surface, and also restricted from bursting to make abnormal noise.

The bubbles 8 can be suppressed from flowing backward to the upstream side in the liquid-phase passage with respect to the connection portion between the liquid-phase passage 6 and the outer bypass passage 71. Consequently, the liquid-phase refrigerant is smoothly supplied from the condenser 4 to the evaporator 3 through the liquid-phase passage 6. Therefore, the device temperature regulator 1 can improve the cooling performance for the battery 2.

### Fourth Embodiment

A fourth embodiment will be described below. The fourth embodiment is substantially the same as the third embodiment except that the configuration of the outer bypass passage 71 is changed with respect to that of the third embodiment, and thus only differences from the third embodiment will be described.

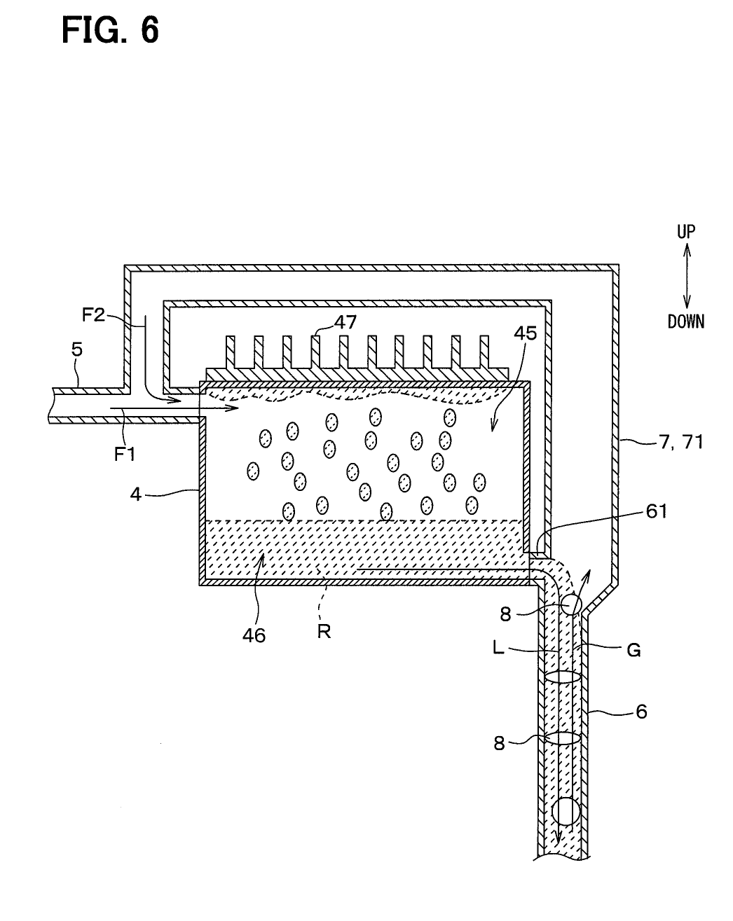

As shown in FIG. 6, in the fourth embodiment, the outer bypass passage 71 has one end connected to the liquid-phase passage 6 and the other end connected to the gas-phase passage 5. When the refrigerant boils in the evaporator 3 and is condensed in the condenser 4 due to a temperature difference between the evaporator 3 and the condenser 4, as indicated by an arrow F1 in FIG. 6, the flow of the gas-phase refrigerant directed from the evaporator 3 to the condenser 4 is generated in the gas-phase passage 5. Thus, the other end of the outer bypass passage 71 is connected to the gas-phase passage 5, so that the gas-phase refrigerant flowing through the outer bypass passage 71 can be drawn into the gas-phase passage 5 due to a negative pressure generated by the flow of the gas-phase refrigerant in the gas-phase passage 5, as indicated by the arrow F2. Therefore, in the fourth embodiment, the pressure loss of the gas-phase refrigerant becomes smaller in the outer bypass passage 71, thereby restricting the bubbles 8 flowing backward through the liquid-phase passage 6 from intruding into the condenser 4. Consequently, the device temperature regulator 1 can suppress the generation of abnormal noise due to the burst of the bubbles 8, while restricting the liquid-phase refrigerant from being blown up from the upper liquid surface in the condenser 4.

### Fifth Embodiment

A fifth embodiment will be described below. The fifth embodiment is substantially the same as the first embodiment except that the configuration of the bypass passage 7 is changed with respect to that of the first embodiment, and thus only differences from the first embodiment will be described.

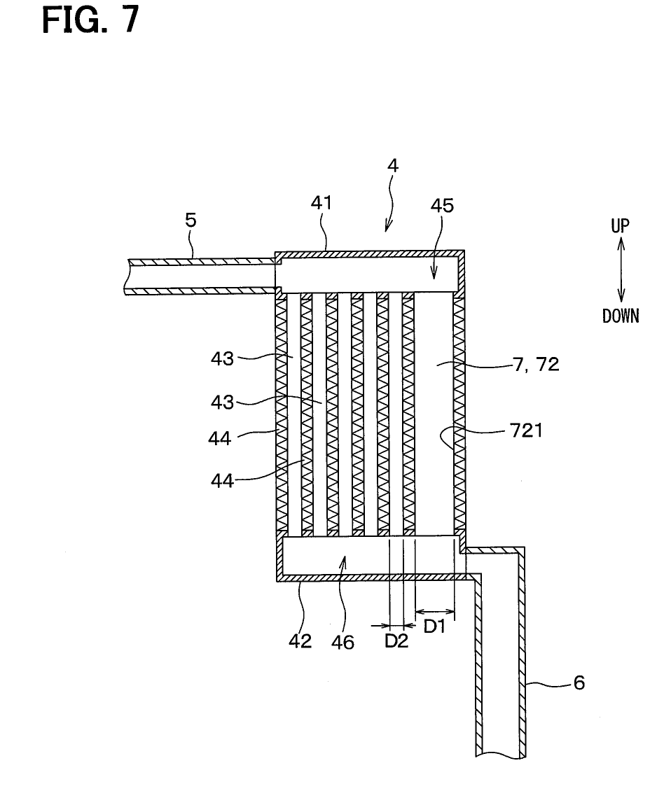

As shown in FIG. 7, in the fifth embodiment, the bypass passage 7 is provided inside the condenser 4. In the fifth embodiment, the bypass passage 7 has one end connected to the liquid-phase portion 46 of the condenser 4 and the other end connected to the gas-phase portion 45 of the condenser 4, and the bypass passage 7 is hereinafter referred to as an inner bypass passage 72. Specifically, the inner bypass passage 72 has one end connected to the lower tank 42 as the liquid-phase portion 46 of the condenser 4 and the other end connected to the upper tank 41 as the gas-phase portion 45 of the condenser 4. The inner bypass passage 72 is formed to have a passage inner diameter D1 that is larger than a passage inner diameter D2 of each of the plurality of heat exchange tubes 43. Alternatively, an equivalent diameter or a passage cross-sectional area of the inner bypass passage 72 may be larger than an equivalent diameter or a passage cross-sectional area of each of the heat exchange tubes 43.

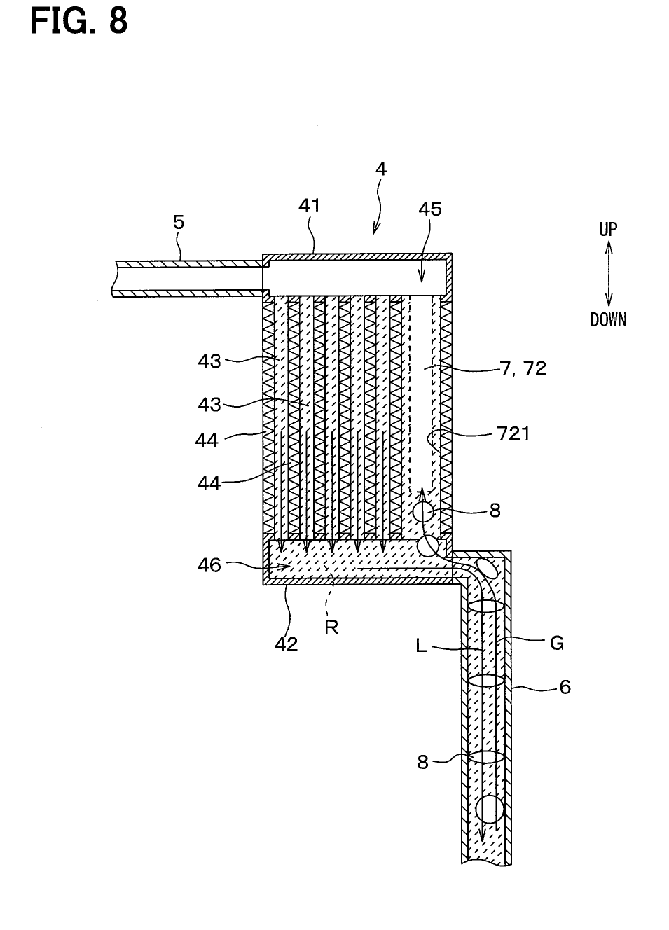

In FIG. 8, the liquid-phase refrigerant formed in the heat exchange tubes 43 of the condenser 4 and flowing from the lower tank 42 through the liquid-phase passage 6 is indicated by hatching R in dotted lines, and the flow direction of the liquid-phase refrigerant is indicated by the arrow L. In FIG. 8, the direction in which the bubbles 8 flow backward against the flow of the liquid-phase refrigerant by the buoyant force is indicated by the arrow G.

As mentioned above, the inner bypass passage 72 is formed to have a larger passage inner diameter, equivalent diameter, or passage cross-sectional area than each of the heat exchange tubes 43 included in the condenser 4. Thus, the liquid-phase refrigerant formed in the inner bypass passage 72 by heat exchange with the external medium outside the condenser 4 flows mainly along an inner peripheral wall 721 of the inner bypass passage 72. Consequently, a region through which the gas-phase refrigerant flows is formed at the center of the inner bypass passage 72. Therefore, the inner bypass passage 72 generates less liquid-phase refrigerant than the plurality of heat exchange tubes 43.

The inner bypass passage 72 is disposed closer to the connection portion between the condenser 4 and the liquid-phase passage 6 than the plurality of heat exchange tubes 43 included in the condenser 4. Thus, the bubbles 8 intruding from the liquid-phase passage 6 into the lower tank 42 tend to easily flow from the lower tank 42 to the inner bypass passage 72. The bubbles 8 flowing to the inner bypass passage are caused to flow from the upper tank 41 of the condenser 4 into the plurality of heat exchange tubes 43 to become a liquid-phase refrigerant.

The device temperature regulator 1 of the fifth embodiment has the following operations and effects.

(1) In the fifth embodiment, the inner bypass passage 72 has one end connected to the lower tank 42 of the condenser 4 and the other end connected to the upper tank 41 of the condenser 4. The inner bypass passage 72 is configured such that the flow rate of the liquid-phase refrigerant per unit volume in the inner bypass passage is smaller than that in the heat exchange tubes 43.

Thus, when entering the liquid-phase portion 46 of the condenser 4 from the liquid-phase passage 6, the bubbles 8 that flow backward against the flow of the liquid-phase refrigerant flowing through the liquid-phase passage 6 tend to flow more easily to the inner bypass passage 72 than to the plurality of heat exchange tubes 43. Consequently, the bubbles 8 can be restricted from entering the heat exchange tubes 43 in the condenser 4. Therefore, the device temperature regulator 1 can restrict the bubbles 8 from pushing up the liquid-phase refrigerant in the heat exchange tubes 43 and blowing up the liquid-phase refrigerant from the upper liquid surface, and can also restrict the bubbles 8 from bursting in the heat exchange tubes 43 to make abnormal noise. Furthermore, the liquid-phase refrigerant can be smoothly formed in the plurality of heat exchange tubes 43 of the condenser 4, so that the liquid-phase refrigerant is smoothly supplied from the condenser 4 to the evaporator 3 through the liquid-phase passage 6. Therefore, the device temperature regulator 1 can improve the cooling performance for the battery 2.

(2) In the fifth embodiment, the inner bypass passage 72 has a larger passage inner diameter, equivalent diameter, or passage cross-sectional area than each of the plurality of heat exchange tubes 43 included in the condenser 4.

Thus, a region through which the gas-phase refrigerant flows can be formed in the inner bypass passage 72. Consequently, the flow rate of the liquid-phase working fluid per unit volume in the inner bypass passage 72 can become smaller than the flow rate of the liquid-phase working fluid per unit volume in the heat exchange tubes 43. Furthermore, the pressure loss of the gas-phase refrigerant flowing through the inner bypass passage 72 can be smaller than the pressure loss of the gas-phase refrigerant flowing backward against the flow of the liquid-phase refrigerant flowing through the heat exchange tubes 43.

(3) In the fifth embodiment, the inner bypass passage 72 is disposed closer to the connection portion between the condenser 4 and the liquid-phase passage 6 than the plurality of heat exchange tubes 43 included in the condenser 4.

Thus, the device temperature regulator 1 can be configured such that when entering the liquid-phase portion 46 of the condenser 4 from the liquid-phase passage 6, the bubbles 8 that flow backward against the flow of the liquid-phase refrigerant flowing through the liquid-phase passage 6 tend to flow more easily to the inner bypass passage 72 than to the plurality of heat exchange tubes 43.

### Sixth Embodiment

A sixth embodiment will be described below. The sixth embodiment is substantially the same as the fifth embodiment except that the configuration of the inner bypass passage 72 is changed with respect to that of the fifth embodiment, and thus only differences from the fifth embodiment will be described.

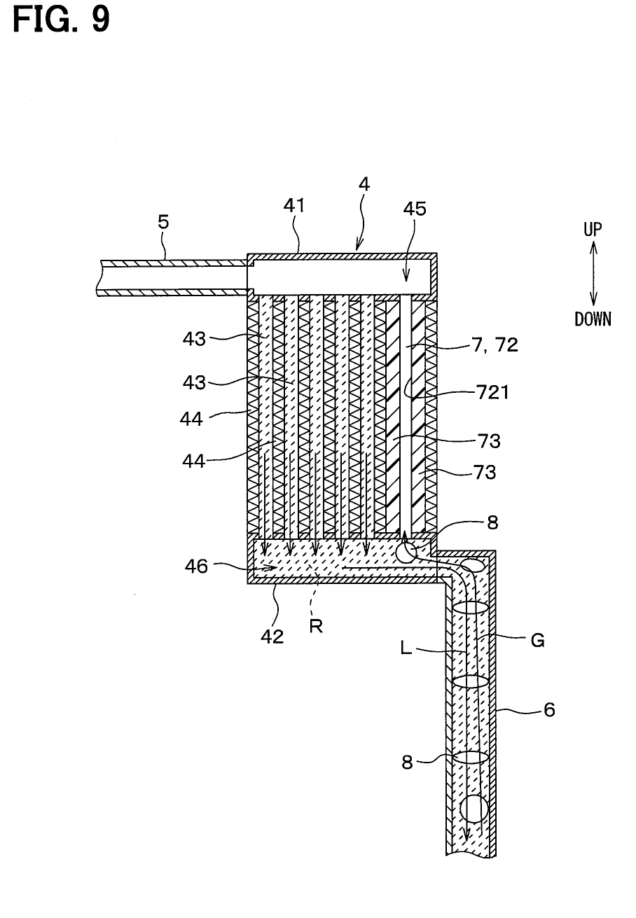

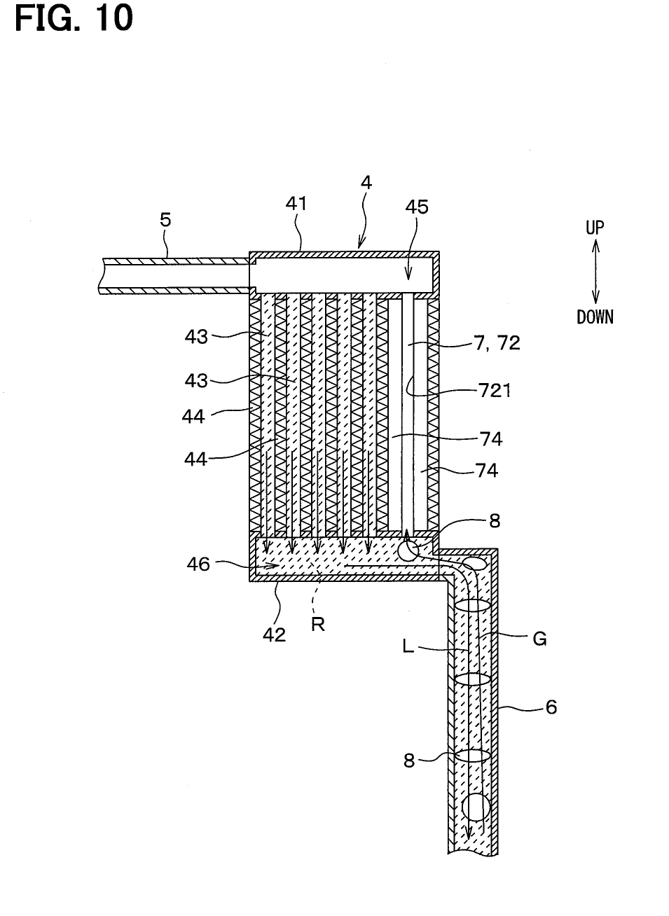

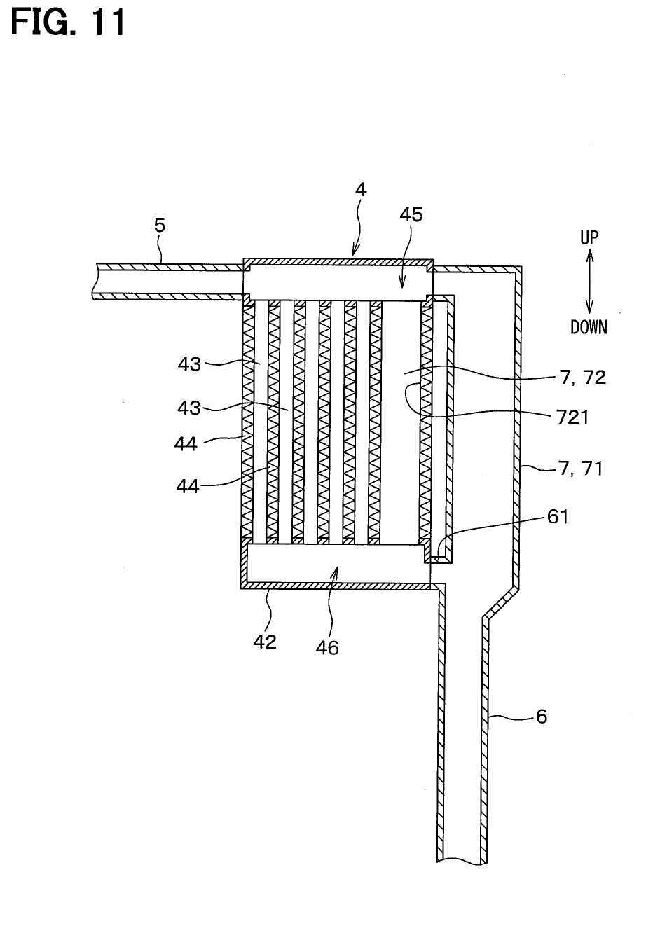

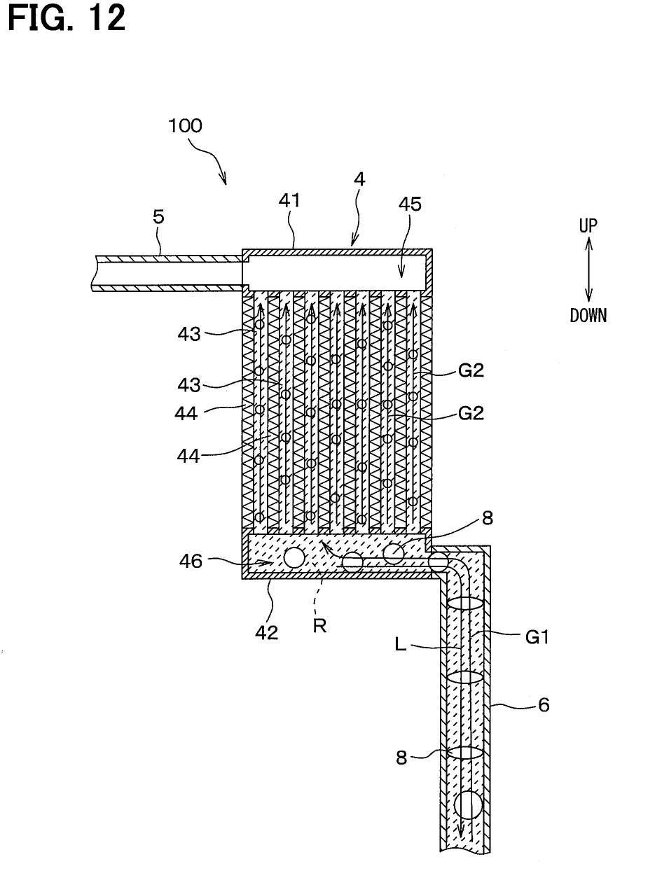

As shown in FIG. 9, in the sixth embodiment, the inner bypass passage 72 is configured to have a lower heat exchange efficiency with the external medium than each of the plurality of heat exchange tubes 43 included in the condenser 4. Specifically, a heat insulation material 73 is provided to cover the outer side of the inner bypass passage 72. Thus, in the inner bypass passage 72, the formation of the liquid-phase refrigerant is suppressed. Consequently, a region through which the gas-phase refrigerant flows is formed at the center of the inner bypass passage 72. Therefore, the inner bypass passage 72 has the configuration in which the flow rate of the liquid-phase working fluid per unit volume is smaller than that in the heat exchange tubes 43. Thus, the sixth embodiment can also exhibit the same functions and effects as the fifth embodiment.

### Seventh Embodiment

A seventh embodiment will be described below. The seventh embodiment is substantially the same as the sixth embodiment except that the configuration of the inner bypass passage 72 is changed with respect to that of the sixth embodiment, and thus only differences from the sixth embodiment will be described.

As shown in FIG. 10, in the seventh embodiment, fins 44 are not provided on the outer side of the inner bypass passage 72. A space 74 with no material provided therein is formed outside the inner bypass passage 72. Thus, the inner bypass passage 72 has a lower heat exchange efficiency with the external medium than each of the plurality of heat exchange tubes 43 included in the condenser 4. Consequently, in the inner bypass passage 72, the formation of the liquid-phase refrigerant is suppressed. Therefore, since the region through which the gas-phase refrigerant flows is formed at the center of the inner bypass passage 72, the inner bypass passage 72 has the configuration in which the flow rate of the liquid-phase working fluid per unit volume is smaller than that in the heat exchange tubes 43. The seventh embodiment mentioned above can also exhibit the same functions and effects as the fifth and sixth embodiments.

### Eighth Embodiment

An eighth embodiment will be described below. The eighth embodiment is a combination of the first embodiment and the fifth embodiment. Thus, by arbitrarily combining the outer bypass passage 71 and the inner bypass passage 72 in the device temperature regulator 1, the bubbles 8 that flow backward against the flow of the liquid-phase refrigerant flowing through the liquid-phase passage 6 tend to easily flow from the liquid-phase passage 6 to the outer bypass passage 71 or the inner bypass passage 72. Therefore, the device temperature regulator 1 can restrict the bubbles 8 from pushing up the liquid-phase refrigerant in the liquid-phase portion 46 of the condenser 4 and blowing up the liquid-phase refrigerant from the upper liquid surface, and can also restrict the bubbles 8 from bursting to make abnormal noise.

### Other Embodiments

The present disclosure is not limited to the above-mentioned embodiments, and various modifications and changes can be made to the embodiments as appropriate. The above-mentioned respective embodiments are not irrelevant to each other, and any combination of the embodiments may be implemented as appropriate except when the combination seems obviously impossible. In the above-mentioned respective embodiments, obviously, any component configuring the embodiments are not necessarily essential unless otherwise specified and except when clearly considered to be essential in principle. In the above-mentioned respective embodiments, when referring to a specific number about the components of the embodiments, such as the number, a numerical value, an amount, and a range of the components, the component should not be limited to the specific number unless otherwise specified, and except when obviously limited to the specific number in principle. When referring to the shape, positional relationship, or the like of components and the like in each of the above-mentioned embodiments, the component should not be limited to the shape, positional relationship, or the like unless otherwise specified and except when limited to the specific shape, positional relationship, or the like in principle.

While in the above-mentioned embodiments, the device temperature regulator 1 is configured to cool, for example, the battery 2 of the vehicle, in other embodiments, the target device cooled by the device temperature regulator 1 may be various devices included in vehicles.

While in the above-mentioned embodiments, the device temperature regulator 1 is configured to cool, for example, the battery 2, in other embodiments, the device temperature regulator 1 may heat the battery 2. In this case, the evaporator 3 condenses the refrigerant, and the condenser 4 evaporates the refrigerant.

For example, in the above-mentioned embodiments, the evaporator 3 is configured of a case formed in a flat shape. Alternatively, in other embodiments, the evaporator 3 may have a configuration including heat exchange tubes.

### SUMMARY

According to a first aspect described in a part or all of the above-mentioned embodiments, a device temperature regulator is configured to regulate a temperature of a target device and includes an evaporator, a condenser, a gas-phase passage, a liquid-phase passage, and a bypass passage. The evaporator includes a fluid chamber in which a working fluid flows, and is configured to cool the target device by latent heat of evaporation when the working fluid in the fluid chamber evaporates by absorbing heat from the target device. The condenser is provided above the evaporator in a gravitational direction and includes a gas-phase portion in which the working fluid evaporated in the evaporator flows and a liquid-phase portion in which the working fluid from the gas-phase portion, condensed by heat exchange with an external medium outside of the condenser, flows;

The gas-phase passage has one end connected to the evaporator and another end connected to the gas-phase portion of the condenser, and causes the working fluid evaporated in the evaporator to flow to the condenser. The liquid-phase passage has one end connected to the evaporator and another end connected to the liquid-phase portion of the condenser and causes the working fluid condensed in the condenser to flow to the evaporator. The bypass passage has one end connected to the liquid-phase portion of the condenser or the liquid-phase passage and another end connected to the gas-phase portion of the condenser or the gas-phase passage. Further, the bypass passage is configured such that a flow rate of a liquid-phase working fluid per unit volume in the bypass passage is smaller than a flow rate of a liquid-phase working fluid per unit volume in the liquid-phase portion of the condenser or the liquid-phase passage.

According to a second aspect, the outer bypass passage has one end connected to the liquid-phase passage and another end connected to the gas-phase portion of the condenser.

Thus, bubbles that flow backward against the flow of the liquid-phase working fluid flowing through the liquid-phase passage tend to easily flow from the liquid-phase passage to the outer bypass passage. Therefore, the bubbles can be restricted from pushing up the liquid-phase working fluid in the liquid-phase portion of the condenser and blowing up the liquid-phase working fluid from the upper liquid surface, and also restricted from bursting to make abnormal noise. Further, the bubbles can be suppressed from flowing backward to the upstream side in the liquid-phase passage with respect to the connection portion between the liquid-phase passage and the bypass passage. Consequently, the liquid-phase working fluid is smoothly supplied from the liquid-phase portion of the condenser to the evaporator through the liquid-phase passage. Therefore, the device temperature regulator can improve the cooling performance for the target device.

According to a third aspect, the outer bypass passage has one end connected to the liquid-phase passage and another end connected to the gas-phase passage.

Thus, the gas-phase working fluid flowing through the outer bypass passage can be drawn into the gas-phase passage by a negative pressure generated by the flow of the gas-phase working fluid in the gas-phase passage. Therefore, the flow of the gas-phase working fluid in the outer bypass passage can be made smooth.

According to the fourth aspect, the liquid-phase passage includes the extending portion extending from the liquid-phase portion of the condenser in a direction intersecting the gravitational direction. The outer bypass passage has one end connected to a part of the extending portion of the liquid-phase passage located on the opposite side to the liquid-phase portion of the condenser.

Thus, the liquid-phase working fluid, which flows out of the liquid-phase portion of the condenser to the liquid-phase passage, flows at a larger flow rate through the part of the extending portion located close to the liquid-phase portion. Consequently, the bubbles that flow backward against the flow of the liquid-phase working fluid flowing through the liquid-phase passage tend to easily flow from the part of the extending portion located far from the liquid-phase portion, to the outer bypass passage. Therefore, the separation efficiency between the liquid-phase working fluid flowing through the liquid-phase passage and the bubbles can be improved.

According to a fifth aspect, the condenser includes an upper tank, a lower tank disposed below the upper tank in the gravitational direction, and a plurality of heat exchange tubes connecting the upper tank and the lower tank. The bypass passage includes an inside bypass passage that has one end connected to the lower tank of the condenser and another end connected to the upper tank of the condenser. The inside bypass passage is configured such that a flow rate of a liquid-phase working fluid per unit volume in the inside bypass passage is smaller than a flow rate of a liquid-phase working fluid per unit volume in the heat exchange tubes.

Thus, when entering the liquid-phase portion of the condenser from the liquid-phase passage, the bubbles that flow backward against the flow of the liquid-phase working fluid flowing through the liquid-phase passage tend to flow more easily to the inner bypass passage than to the plurality of heat exchange tubes. Consequently, the bubbles can be restricted from entering the heat exchange tubes in the condenser. Therefore, the bubbles can be restricted from pushing up the liquid-phase working fluid in the heat exchange tubes and blowing up the liquid-phase working fluid from the upper liquid surface, and also restricted from bursting in the heat exchange tubes to make abnormal noise. The liquid-phase working fluid can be smoothly formed in the plurality of heat exchange tubes of the condenser, so that the liquid-phase working fluid is smoothly supplied from the condenser to the evaporator through the liquid-phase passage. Therefore, the device temperature regulator can improve the cooling performance for the target device.

According to a sixth aspect, the inner bypass passage has a larger passage inner diameter, equivalent diameter, or passage cross-sectional area than each of the plurality of heat exchange tubes included in the condenser.

Thus, a region through which the gas-phase working fluid flows can be formed in the inner bypass passage. Consequently, the pressure loss of the gas-phase working fluid flowing through the inner bypass passage can be made smaller than the pressure loss of the gas-phase working fluid that flows backward against the flow of the liquid-phase working fluid flowing through the heat exchange tubes.

According to a seventh aspect, the inner bypass passage is configured to have a lower heat exchange efficiency with the external medium outside of the condenser than each of the plurality of heat exchange tubes included in the condenser.

Thus, the liquid-phase working fluid can be restricted from being formed in the inner bypass passage, so that a region through which the gas-phase working fluid flows can be formed in the inner bypass passage. Therefore, the pressure loss of the gas-phase working fluid flowing through the inner bypass passage can be made smaller than the pressure loss of the gas-phase working fluid that flows backward against the flow of the liquid-phase working fluid flowing through the heat exchange tubes.

According to an eighth aspect, the inner bypass passage is disposed closer to a portion where the condenser and the liquid-phase passage are connected than the plurality of heat exchange tubes included in the condenser.

Thus, when entering the liquid-phase portion of the condenser from the liquid-phase passage, the bubbles that flow backward against the flow of the liquid-phase working fluid flowing through the liquid-phase passage can flow more easily to the inner bypass passage than to the plurality of heat exchange tubes.

According to a ninth aspect, a device temperature regulator is configured to regulate a temperature of a target device and includes an evaporator, a condenser, a gas-phase passage, a liquid-phase passage, and an outer bypass passage. The evaporator includes a fluid chamber in which a working fluid flows, and cools the target device by latent heat of evaporation when the working fluid in the fluid chamber evaporates by absorbing heat from the target device. The condenser is provided above the evaporator in a gravitational direction. The condenser includes a gas-phase portion in which the working fluid evaporated in the evaporator flows and a liquid-phase portion in which the working fluid from the gas-phase portion, condensed by heat exchange with an external medium outside of the condenser, flows.

The gas-phase passage has one end connected to the evaporator and another end connected to the gas-phase portion of the condenser, and causes the working fluid evaporated in the evaporator to flow to the condenser. The liquid-phase passage has one end connected to the evaporator and another end connected to the liquid-phase portion of the condenser and causes the working fluid condensed in the condenser to flow to the evaporator. The outer bypass passage has one end connected to the liquid-phase passage and another end connected to the gas-phase portion of the condenser or the gas-phase passage. Further, the outer bypass passage is configured such that a flow rate of a liquid-phase working fluid per unit volume in the outer bypass passage is smaller than a flow rate of a liquid-phase working fluid per unit volume in the liquid-phase passage.

Thus, bubbles that flow backward against the flow of the liquid-phase working fluid flowing through the liquid-phase passage tend to easily flow from the liquid-phase passage to the outer bypass passage. Therefore, the bubbles can be restricted from pushing up the liquid-phase working fluid in the liquid-phase portion of the condenser and blowing up the liquid-phase working fluid from the upper liquid surface, and also restricted from bursting to make abnormal noise. Further, the bubbles can be suppressed from flowing backward to the upstream side in the liquid-phase passage with respect to the connection portion between the liquid-phase passage and the bypass passage. Consequently, the liquid-phase working fluid is smoothly supplied from the liquid-phase portion of the condenser to the evaporator via the liquid-phase passage. Therefore, the device temperature regulator can improve the cooling performance for the target device.

According to a tenth aspect, a device temperature regulator is configured to regulate a temperature of a target device and includes an evaporator, a condenser, a gas-phase passage, a liquid-phase passage, and an inner bypass passage. The evaporator includes a fluid chamber in which a working fluid flows, and cools the target device by latent heat of evaporation when the working fluid in the fluid chamber evaporates by absorbing heat from the target device. The condenser is provided above the evaporator in a gravitational direction, and includes an upper tank, a lower tank disposed below the upper tank in the gravitational direction, and a plurality of heat exchange tubes connecting the upper tank and the lower tank. The condenser condenses the working fluid by heat exchange with an external medium located outside. The gas-phase passage has one end connected to the evaporator and another end connected to the upper tank of the condenser and causes the working fluid evaporated in the evaporator to flow to the condenser. The liquid-phase passage has one end connected to the evaporator and another end connected to the lower tank of the condenser and causes the working fluid condensed in the condenser to flow to the evaporator. The inner bypass passage has one end connected to the lower tank of the condenser and another end connected to the upper tank of the condenser. Further, the inner bypass passage is configured such that a flow rate of a liquid-phase working fluid per unit volume in the inner bypass passage is smaller than a flow rate of a liquid-phase working fluid per unit volume in the heat exchange tubes.

Thus, when entering the liquid-phase portion of the condenser from the liquid-phase passage, the bubbles that flow backward against the flow of the liquid-phase working fluid flowing through the liquid-phase passage tend to flow more easily to the inner bypass passage than to the plurality of heat exchange tubes. Consequently, the bubbles can be restricted from entering the heat exchange tubes in the condenser. Therefore, the bubbles can be restricted from pushing up the liquid-phase working fluid in the heat exchange tubes and blowing up the liquid-phase working fluid from the upper liquid surface, and also restricted from bursting in the heat exchange tubes to make abnormal noise. Since the liquid-phase working fluid is smoothly formed in the plurality of heat exchange tubes of the condenser, the liquid-phase working fluid is smoothly supplied from the condenser to the evaporator through the liquid-phase passage. Therefore, the device temperature regulator can improve the cooling performance for the target device.

1. A device temperature regulator for regulating a temperature of a target device, comprising:
an evaporator including a fluid chamber in which a working fluid flows, the evaporator being configured to cool the target device by latent heat of evaporation when the working fluid in the fluid chamber evaporates by absorbing heat from the target device;
a condenser provided above the evaporator in a gravitational direction, the condenser including a gas-phase portion in which the working fluid evaporated in the evaporator flows and a liquid-phase portion in which the working fluid from the gas-phase portion, condensed by heat exchange with an external medium outside of the condenser, flows;
a gas-phase passage that has one end connected to the evaporator and another end connected to the gas-phase portion of the condenser, the gas-phase passage causing the working fluid evaporated in the evaporator to flow to the condenser;
a liquid-phase passage that has one end connected to the evaporator and another end connected to the liquid-phase portion of the condenser, the liquid-phase passage causing the working fluid condensed in the condenser to flow to the evaporator; and
a bypass passage that has one end connected to the liquid-phase portion of the condenser or the liquid-phase passage and another end connected to the gas-phase portion of the condenser or the gas-phase passage, the bypass passage being configured such that a flow rate of a liquid-phase working fluid per unit volume in the bypass passage is smaller than a flow rate of a liquid-phase working fluid per unit volume in the liquid-phase portion of the condenser or the liquid-phase passage.

2. The device temperature regulator according to claim 1, wherein
the bypass passage includes an outer bypass passage that has one end connected to the liquid-phase passage and another end connected to the gas-phase portion of the condenser.

3. The device temperature regulator according to claim 1, wherein
the bypass passage includes an outer bypass passage that has one end connected to the liquid-phase passage and another end connected to the gas-phase passage.

4. The device temperature regulator according to claim 2, wherein
the liquid-phase passage includes an extending portion extending from the liquid-phase portion of the condenser in a direction intersecting the gravitational direction, and
the outer bypass passage has the one end connected to a part of the extending portion of the liquid-phase passage located on an opposite side to the liquid-phase portion of the condenser.

5. The device temperature regulator according to claim 1, wherein
the condenser includes an upper tank, a lower tank disposed below the upper tank in the gravitational direction, and a plurality of heat exchange tubes connecting the upper tank and the lower tank, and
the bypass passage includes an inside bypass passage that has one end connected to the lower tank of the condenser and another end connected to the upper tank of the condenser, the inside bypass passage being configured such that a flow rate of a liquid-phase working fluid per unit volume in the inside bypass passage is smaller than a flow rate of a liquid-phase working fluid per unit volume in the heat exchange tubes.

6. The device temperature regulator according to claim 5, wherein
the inner bypass passage has a passage inner diameter, an equivalent diameter, or a passage cross-sectional area larger than each of the plurality of heat exchange tubes included in the condenser.

7. The device temperature regulator according to claim 5, wherein
the inner bypass passage is configured to have a heat exchange efficiency with the external medium outside the condenser, lower than that of each of the plurality of heat exchange tubes included in the condenser.

8. The device temperature regulator according to claim 5, wherein
the inner bypass passage is disposed closer to a portion where the condenser and the liquid-phase passage are connected, than the plurality of heat exchange tubes included in the condenser.

9. A device temperature regulator for regulating a temperature of a target device, comprising:
an evaporator including a fluid chamber in which a working fluid flows, the evaporator being configured to cool the target device by latent heat of evaporation when the working fluid in the fluid chamber evaporates by absorbing heat from the target device;
a condenser provided above the evaporator in a gravitational direction, the condenser including a gas-phase portion in which the working fluid evaporated in the evaporator flows and a liquid-phase portion in which the working fluid from the gas-phase portion, condensed by heat exchange with an external medium outside of the condenser, flows;
a gas-phase passage that has one end connected to the evaporator and another end connected to the gas-phase portion of the condenser, the gas-phase passage causing the working fluid evaporated in the evaporator to flow to the condenser;
a liquid-phase passage that has one end connected to the evaporator and another end connected to the liquid-phase portion of the condenser, the liquid-phase passage causing the working fluid condensed in the condenser to flow to the evaporator; and
an outer bypass passage that has one end connected to the liquid-phase passage and another end connected to the gas-phase portion of the condenser or the gas-phase passage, the outer bypass passage being configured such that a flow rate of a liquid-phase working fluid per unit volume in the outer bypass passage is smaller than a flow rate of a liquid-phase working fluid per unit volume in the liquid-phase passage.

10. A device temperature regulator for regulating a temperature of a target device, comprising:
an evaporator including a fluid chamber in which a working fluid flows, the evaporator being configured to cool the target device by latent heat of evaporation when the working fluid in the fluid chamber evaporates by absorbing heat from the target device;
a condenser provided above the evaporator in a gravitational direction, the condenser including an upper tank, a lower tank disposed below the upper tank in the gravitational direction, and a plurality of heat exchange tubes connecting the upper tank and the lower tank, the condenser being configured to condense the working fluid by heat exchange with an external medium outside of the condenser;
a gas-phase passage that has one end connected to the evaporator and another end connected to the upper tank of the condenser, the gas-phase passage causing the working fluid evaporated in the evaporator to flow to the condenser;
a liquid-phase passage that has one end connected to the evaporator and another end connected to the lower tank of the condenser, the liquid-phase passage causing the working fluid condensed in the condenser to flow to the evaporator; and
an inner bypass passage that has one end connected to the lower tank of the condenser and another end connected to the upper tank of the condenser, the inner bypass passage being configured such that a flow rate of a liquid-phase working fluid per unit volume in the inner bypass passage is smaller than a flow rate of a liquid-phase working fluid per unit volume in the heat exchange tubes.
